(19) United States
(12) Patent Application Publication
(10) Pub. No.: US 2004/0188690 A1
(43) Pub. Date: Sep. 30, 2004

(54) Light emitting diode

(75) Inventor: Takafumi Noguchi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/809,520

(22) Filed: Mar. 26, 2004

(30) Foreign Application Priority Data
Mar. 26, 2003 (JP) P.2003-085832

(51) Int. Cl. H01L 27/15

(52) U.S. Cl. 257/79

(57) ABSTRACT

A light emitting diode comprising: a pair of electrodes; and a light emitting layer interposed between the pair of electrodes, wherein the light emitting layer has a light emitting region containing a luminescent material and having a higher refractive index than air and a low refractive region having a lower refractive index than the light emitting region, and at least part of an interface between the light emitting region and the low refractive region is unparallel to a plane of the electrodes.

### FIELD OF THE INVENTION

This invention relates to a light emitting diode having high light extraction efficiency and, more particularly, a self-emissive device having a higher refractive index in its luminescent region than air, including organic light emitting diodes (OLEDs) and inorganic light emitting diodes (LEDs).

### BACKGROUND OF THE INVENTION

Self-emissive devices, such as OLEDs and IELDs, are promising for applications, such as a planar light source for full color displays, backlight units, and illumination systems or a light source array of printers and have been actively studied. In particular, organic light emitting diodes using organic compounds, such as OLEDs, are characterized by thinness, light weight, short response time, wide viewing angle, and low power consumption and are ready to be applied to planar light emitting devices. Therefore they are promising light-emitting devices for inexpensive, wide-screen, full-color solid-state light emitting devices, light source arrays for writing, and so forth.

OLEDs and IELDs with such excellent characteristics are generally composed of thin films, including the light emitting layer, having higher refractive indices than air. For example, organic thin layers, such as a light emitting layer, that compose an OLED each have a thickness of 10 to 200 nm and a refractive index of 1.6 to 2.1. Therefore, the generated light is liable to total internal reflection on the interfaces or optical interference. As a result, most of the generated light is lost, and the light extraction efficiency does not reach 20%.

The optical loss in an OLED will be briefly explained with reference to FIG. 6. As shown in FIG. 6, an OLED basically has a transparent substrate 1, a transparent electrode 2, an organic layer 33 which is a stack of two or three layers including a light emitting layer, and a back electrode 4 in that order. Positive holes injected from the transparent electrode 2 and electrons injected from the back electrode 4 are re-combined in the organic layer 33 to excite a luminescent material, e.g., a fluorescent material to generate light. The light generated in the organic layer 33 is emitted from the transparent substrate 1. The light reflected on the back electrode 4 formed of aluminum, etc. is also emitted from the transparent substrate 1.

However, some of the light generated inside the device is totally reflected on the interfaces between adjacent layers having different refractive indices depending on the incident angle and waveguided and trapped within the device (the light rays Lc and Lb in FIG. 6). The proportion of light waveguided inside the device is governed by the relative refractive indices of adjacent layers. In the case of an ordinary OLED (air (n=1.0)/transparent substrate (n≈1.5)/transparent electrode (n≈2.0)/organic layer (n≈1.7)/back electrode), the proportion of the light waveguided inside the device and not emitted into the atmosphere (air) is about 81%. Namely, only about 19% of the generated light can be made effective use of.

In order to increase the light extraction efficiency, it is necessary to take measures for extracting (a) the light totally reflected on the transparent substrate/air interface and propagated through the organic layer/transparent electrode/transparent substrate (light Lb of FIG. 6) and (b) the light totally reflected on the transparent electrode/transparent substrate interface and propagated through the organic layer/transparent electrode (the light Lc of FIG. 6).

With respect to the light Lb, it has been proposed to roughen the surface of the transparent substrate to reduce the total reflection on the transparent substrate/air interface as disclosed, e.g., in U.S. Pat. No. 4,774,435.

As for the light Lc, it has been proposed to provide a diffraction grating interface between the transparent electrode and the transparent substrate or between the light emitting layer and the adjacent layer as disclosed, e.g., in JP-A-11-283751 and JP-A-2002-313554. It is also suggested to roughen the interface between adjacent organic layers to improve light extraction efficiency as disclosed, e.g., in JP-A-2002-313567. In detail, according to the technique of forming a diffraction grating in the light emitting layer/adjacent layer interface, the adjacent layer is made of a conductive medium, the depth of the diffraction grating is about 40% of the light emitting layer's thickness, and the relationship between the pitch and the depth of the grating is specified to let out the trapped light. According to the technique of roughening the interface between organic layers, the layers on both sides of the interface are made of conductive media, and an interfacial roughness having a depth of about 20% of the light emitting layer's thickness and an angle of inclination of about 30° is formed between organic layers to provide an increased interfacial contact area thereby improving light extraction efficiency.

### SUMMARY OF THE INVENTION

However, the proposed techniques involve difficulty in fabrication and tendency to dielectric breakdown on voltage application. It has therefore been demanded to establish a technique for increasing light extraction efficiency of light emitting devices.

An object of the present invention is to provide a method of easily fabricating a self-emissive device having a higher refractive index in its luminescent region than air and featuring an improved light extraction efficiency without involving a tendency to dielectric breakdown during use and to provide a light emitting diode having a high light extraction efficiency. In particular, it is an object of the invention to provide an OLED from which light waveguided through the organic layer/transparent electrode can be extracted more efficiently.

The object of the invention is accomplished by a light emitting diode having a light emitting layer between a pair of electrodes, wherein the light emitting layer has a light emitting region containing a luminescent material and having a higher refractive index than air and a low refractive region having a lower refractive index than the light emitting region. At least part of the interface between the light emitting region and the low refractive region is unparallel to the plane of the electrodes.

At least part of the interface between the light emitting region and the low refractive region is preferably perpendicular to the plane of the electrodes.

The low refractive region preferably contains air as a medium.

The light emitting diode of the invention is preferably an OLED, in which the light emitting region is formed of an organic compound.

According to the present invention, intentional incorporation of a low refractive region having a lower refractive index than a light emitting region into the light emitting layer makes it possible to extract waveguided light thereby to improve the light extraction efficiency. The mechanism of action of the low refractive region is explained by referring to FIG. 1. The device of FIG. 1 has a transparent substrate 1, a transparent electrode 2, a light emitting layer 3, and a back electrode 4. Where the light emitting layer 3 has a light emitting region 8 and a low refractive region 5 arranged with their interface 6 being unparallel to the plane of the electrodes, namely, the interface between the light emitting layer 3 and each electrode as shown in FIG. 1, generated light is refracted at the interface 6 and changes its propagation direction from the dotted line to the solid line. As a result, there is created a path through which light can escape from the device without totally reflecting on the interfaces between the transparent electrode 2 and the transparent substrate 1 and between the transparent substrate 1 and air. This seems to account for the improvement on light extraction efficiency obtained by the invention.

The angle formed between the light emitting region/low refractive region interface and the plane of the electrodes (i.e., the interface between the light emitting layer 3 and the electrodes 1 and 4 in FIG. 1) is preferably 60° or greater, still preferably 90°. As that angle gets closer to 90°, the light extraction efficiency increases probably for the following reason. According as the light emitting region/low refractive region interface gets closer to 90°, the incident angle (the angle between an incident ray and the normal to a surface at the point of incidence) of the light refracted at that interface on the transparent electrode/transparent substrate interface and the transparent substrate/air interface is reduced. It follows that the amount of the refracted light that is not reflected on the transparent electrode/transparent substrate interface and the transparent substrate/air interface is reduced to increase the amount of the refracted light that is emitted outside the device.

It is preferred that the ratio of the refractive index of the low refractive region 5 to that of the light emitting region 8 (i.e., relative refractive index) be as small as possible to make light be refracted more to guide the light path toward the outside of the device. It is particularly preferred that the medium of the low refractive region be air. Air, whose refractive index is as low as 1.0, is effective to reduce the relative refractive index. Besides, it is easy to introduce a low refractive region of air in the light emitting layer.

### BRIEF DESCRIPTION OF THE DRAWINGS

FIG. 1 schematically illustrates a path of light generated in a light emitting layer of a light emitting diode according to the present invention.

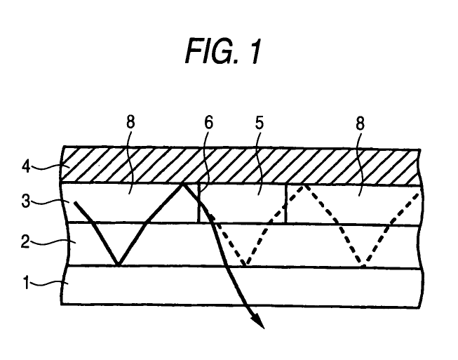

FIG. 2 (FIGS. 2A to 2F) and FIG. 3 (FIGS. 3G to 3I) each show configurations of a low refractive region according to the present invention.

FIG. 4(FIGS. 4A to 4D) represents a flow chart for making a micropatterned organic layer.

FIG. 5 shows a pattern of a light emitting layer (pixels) of the multi-color OLED prepared in Example 2.

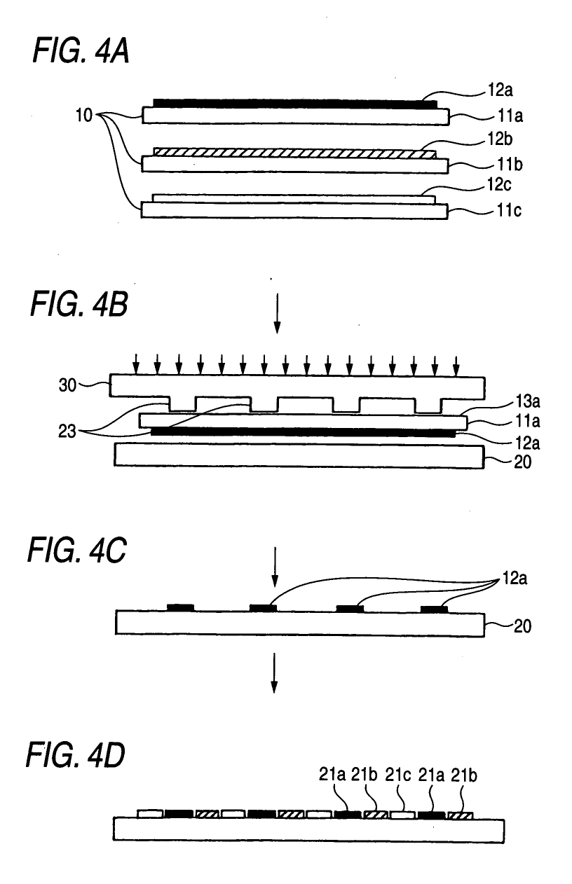

FIG. 6 schematically illustrates a path of light generated in a light emitting layer of a conventional OLED.

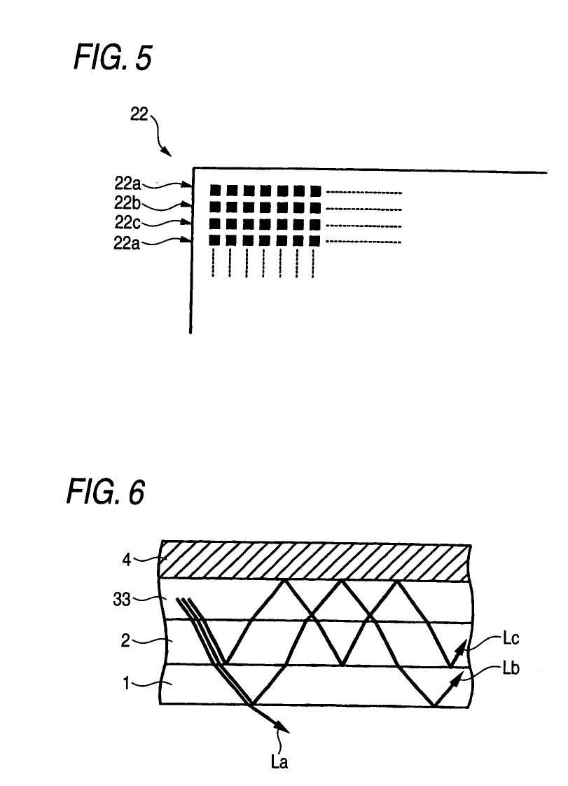

### DETAILED DESCRIPTION OF THE INVENTION

The present invention will further be described with reference to its illustrative embodiments.

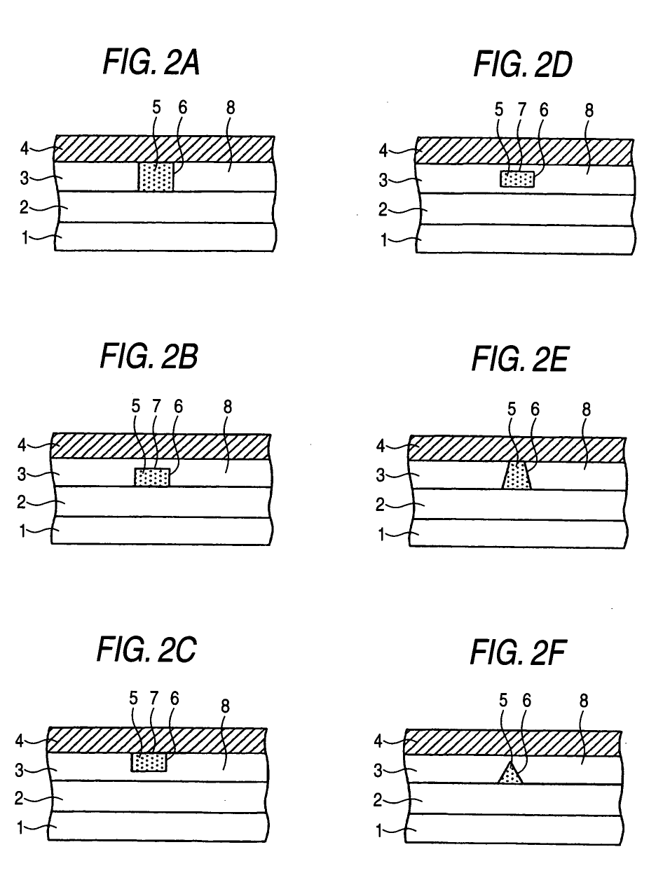

The light emitting diode of the invention has a pair of electrodes and a light emitting layer sandwiched between the electrodes. The light emitting layer contains a light emitting region containing a luminescent material and having a higher refractive index than air and a low refractive region having a lower refractive index than the light emitting region. At least one of the interfaces 6 and 7 (see FIG. 2) formed between the light emitting region and the low refractive region is unparallel to the plane of the electrodes. The interface unparallel to the plane of the electrodes is given numeral 6.

Various configurations of the light emitting region 8 and the low refractive region 5 are illustrated in FIGS. 2 and 3. Light generated in the light emitting layer 3 is emitted from the transparent substrate 1 either directly or indirectly (after reflected on the back electrode 4). The light emitting layer 3 is composed of the light emitting region 8, and the low refractive region 5. The interface 6 between these two'regions is unparallel to the interface between the light emitting layer 3 and the electrode 2 or 4.

The effects of the invention are not affected by whether or not the low refractive region 5 is in contact with at least one of the two adjacent layers on the side of the transparent electrode 1 and on the side of the back electrode 4. That is, the low refractive region 5 may be in contact with both adjacent layers of the light emitting layer as in FIGS. 2A and 2E or either one of the adjacent layers as in FIGS. 2B, 2C, 2F, 3G, 3H, and 3I; or may not be in contact with either adjacent layer as in FIG. 2D. It is particularly preferred that the low refractive region 5 be in contact with both the adjacent layers for causing all the waveguided light rays to change their propagation directions thereby to improve the light extraction efficiency of the device.

Of the interfaces 6 and 7 between the light emitting region 8 and the low refractive region 5, the interface 6 which is unparallel to the plane of the electrodes may be perpendicular (FIGS. 2A to 2D) or oblique (FIGS. 2E and 2F) to the plane of the electrodes, i.e., the interface between the light emitting layer 3 and the electrode 4 or 1, or curved (FIGS. 3G to 3I). For the above-described reason, the angle formed between the interfaced and the plane of the electrodes is preferably, 60° or greater, still preferably 90°. The low refractive region 5 maybe present, in the light emitting layer periodically. (FIG. 3H). The low refractive region 5 may be provided in the form of a layer adjoining the light emitting region 8 (FIG. 3I).

The height of the interface 6 of the low refractive region 5 in the thickness direction of the light emitting layer is preferably 50% or more of the light emitting layer's thickness in order to extract waveguided light efficiently without impairing other characteristics required of a light emitting diode. The width of the low refractive region 5 in the planar direction of the light emitting layer is preferably at least times the height of the interface 6.

The medium that forms the low refractive region 5 includes air and organic or inorganic compounds having a lower refractive index than the light emitting region 8. Aerogel described in Advanced Materials, 2001, 1149 is also useful. It is particularly preferred that the low refractive region 5 be made of air for the above-mentioned reason.

As stated above, the refractive index ratio of the low refractive region 5 to the light emitting region 8, i.e., the relative refractive index is preferably as small as possible. Specifically, the relative refractive index is preferably 0.85 or smaller, still preferably 0.7 or smaller.

The light emitting diodes of the invention include OLEDs containing an organic compound as a luminescent material and IELDs containing an inorganic compound as a luminescent material. The OLED will be described in more detail as an embodiment of the present invention. The same description applies to IELDs, except for the refractive index of the light emitting layer.

Layer structures of OLEDs include (i) transparent electrode/light emitting layer/back electrode, (ii) transparent electrode/light emitting layer/electron transporting layer/back electrode, (iii) transparent electrode/hole transporting layer/light emitting layer/electron transporting layer/back electrode, (iv) transparent electrode/hole transporting layer/light emitting layer/back electrode, (v) transparent electrode/light emitting layer/electron transporting layer/electron injecting layer/back electrode, and (vi) transparent electrode/hole injecting layer/hole transporting layer/light emitting layer/electron transporting layer/electron injecting layer/back electrode, each provided on the substrate in the order described or the reverse order. The light emitting layer contains a fluorescent compound and/or a phosphorescent compound as a luminescent material. Light is usually emitted from the transparent electrode side. Each of the light emitting layer, electron transporting layer, electron injecting layer, hole transporting layer, and hole injecting layer is an organic layer formed of an organic compound. Examples of the organic compounds used to form these organic layers are described, e.g. in Monthly DISPLAY December issue 1998. (separate volume “Yuki EL Display”) by Techno Times Co., Ltd.

The light emitting layer is composed of a light emitting region containing a luminescent material and low refractive region having a lower refractive index than the light emitting region. The low refractive region may be provided in not only the light emitting layer but all the other organic layers.

The low refractive region can be formed by making a groove of prescribed shape in an organic layer (at least the light emitting layer, hereinafter the same) formed by coating or vacuum deposition and filling the groove with a material having a lower refractive index than the other part of the layer by coating or vacuum deposition using a mask. In using air as a filling material, formation of the low refractive region is easier because the step of filling the groove is unnecessary.

Formation of the groove of prescribed shape in an organic layer can be carried out by, for example, micropatterning the organic layer. Micropatterning techniques include chemical etching by photolithography, physical etching by laser machining, vacuum deposition or sputtering through a mask, lift-off process, and printing.

The low refractive region can also be provided by forming a micropatterned organic layer by utilizing a transfer material having an organic layer on a carrier film.

The micropatterned organic layer can be formed (i) by using a micromask having a pattern of fine openings or (ii) by a transfer method using a transfer material having a micropattern of an organic layer on a carrier film, which is superposed on a substrate (a layer on which a micropatterned organic layer is to be formed) to transfer the micropatterned organic layer to the substrate. The transfer material having a micropatterned organic layer on a carrier film is prepared by pressing a transfer material having a non-patterned organic layer on a carrier film from its carrier film side with a pressing member having projections and depressions in a prescribed pattern onto another carrier film.

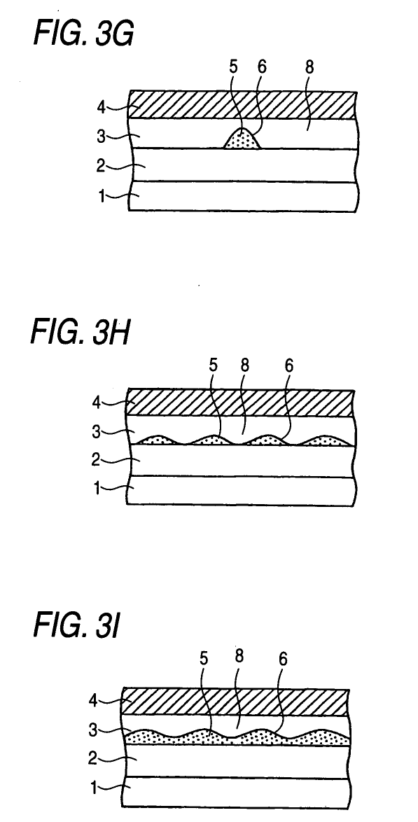

The steps for forming a micropatterned organic layer in accordance with the transfer method (ii) are shown in FIG. 3. To begin with, transfer materials 11a, 11b, and 11c having the respective organic layers 12a, 12b, and 12c formed on the respective carriers 10 are prepared (see FIG. 4A). One of the transfer materials, e.g., the transfer material 11a is superposed on a base 20 with the organic layer 12a in contact with the base 20. A pressing member 30 having projections 23 in a prescribed pattern on its surface is pressed to the carrier side 13a of the transfer material 11a opposite the organic layer 12a (see FIG. 4B), whereby the parts of the organic layer 12a that correspond to the projections 23 are transferred to the base 20 (see FIG. 4C). The same steps are repeated with the transfer materials 11b and 11c thereby to form a pattern of organic layers 21a, 21b, and 21c. Thus, low refractive regions with a desired width can be formed by changing the gap between the organic layers 21a, 21b, and 21c.

Where in using a low refractive material other than air, such as an organic compound having a lower refractive index than air, a transfer material having a layer of the low refractive material on a carrier film is prepared, and the low refractive material is patternwise transferred into the gaps in the same manner as described above.

By changing the composition of the organic layers 12a, 12b, and 12c, it is possible to fabricate a multicolor OLED having organic layers different in luminescent wave form in a side-by-side configuration. For the details of forming micropatterned organic layers, reference can be made in JP-B-2003-139944.

The light emitting layer contains at least one luminescent compound. The luminescent compound may be a fluorescent compound, a phosphorescent compound or a combination thereof.

A phosphorescent compound is preferred in the present embodiment from the standpoint of luminance and luminescence efficiency.

Useful fluorescent compounds include benzoxazole derivatives, benzimidazole derivatives, benzothiazole derivatives, styrylbenzene derivatives, polyphenyl derivatives, diphenylbutadiene derivatives, tetraphenylbutadiene derivatives, naphthylimide derivatives, coumarin derivatives, perylene derivatives, perinone derivatives, oxadiazole derivatives, aldazine derivatives, pyrralidine derivatives, cyclopentadiene derivatives, bisstyrylanthracene derivatives, quinacridone derivatives, pyrrolopyridine derivatives, thiadiazolopyridine derivatives, styrylamine derivatives, aromatic dimethylidyne compounds; metal complexes typified by metal complexes or rare earth element complexes of 8-quinolinol derivatives; and polymers, such as polythiophene derivatives, polyphenylene derivatives, polyphenylene vinylene derivatives, and polyfluorene derivatives. These fluorescent compounds can be used either individually or as a mixture of two or more thereof.

The phosphorescent compounds preferably include, but are not limited to, ortho-metalated complexes and porphyrin complexes. Of porphyrin complexes are preferred porphyrin platinum complexes. The phosphorescent compounds can be used either individually or as a combination of two or more thereof.

“Ortho-metalated complex” is a generic term given to the compounds described, e.g., in Yamamoto Akio, Yukikinzokukagaku-kiso to ohyo, Shokabo Publishing Co., 1982, p150 and 232 and H. Yersin, Photochemistry and Photophysics of Coordination Compounds, Springer-Verlag, 1987, pp. 71-77 and 135-146.

The ligands which form the ortho-metalated complexes preferably include, but are not limited to, 2-phenylpyridine derivatives, 7,8-benzoquinoline derivatives, 2-(2-thienyl)pyridine derivatives, 2-(1-naphthyl)pyridine derivatives, and 2-phenylqinoline derivatives. These derivatives may have a substituent according to necessity. The ortho-metalated complexes can have other ligands in addition to the above-recited ones. Any transition metal can be used as a center metal of the ortho-metalated complexes. In this particular embodiment, rhodium, platinum, gold, iridium, ruthenium, and palladium are preferred.

The organic light emitting layer containing the ortho-metalated complex is advantageous in terms of luminance and luminescence efficiency. Specific examples of useful ortho-metalated complexes are described in Japanese Patent Application No. 2000-254171. The ortho-metalated complexes which can be used in the invention are synthesized according to various known techniques, such as those described in Inorg. Chem., 1991, 30, 1685, ibid., 1988, 27, 3464, ibid., 1994, 33, 545, Inorg. Chim. Acta, 1991, 181, 245, J. Organomet. Chem., 1987, 335, 293, and J. Am. Chem. Soc., 1985, 107, 1431.

The concentration of the luminescent compound in the light emitting layer is not particularly limited but is preferably 0.1 to 70% by weight, more preferably 1 to 20% by weight.

If desired, the light emitting layer can further contain a host material, a hole transporting material, an electron transporting material, an electrically inert binder resin, etc. Some compounds function two or more functions of these functional materials. For example, carbazole derivatives function as not only a host material but a hole transporting material.

The terminology “host material” as used herein means a compound which transfers energy from its excited state to a luminescent compound thereby causing the luminescent compound to emit light. Examples of such materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic (e.g., naphthalene or perylene) tetracarboxylic acid anhydrides, phthalocyanine derivatives, metal complexes of 8-quinolinol derivatives, methallo-phthalocyanines, metal complexes having benzoxazole, benzothiazole, etc. as a ligand, polysilane compounds, poly(N-vinylcarbazole) derivatives, aniline copolymers, conductive polymers (e.g., thiophene oligomers and polythiophene), polythiophene derivatives, polyphenylene derivatives, polyphenylene vinylene derivatives, and polyfluorene derivatives. They can be used either individually or as a combination of two or more thereof.

The host material concentration in the light emitting layer is preferably 0 to 99.9% by weight, still preferably 0 to 99.0% by weight.

The hole transporting materials which can be used in the invention are not limited, whether low-molecular or high-molecular, as long as any one of a function of injecting holes from the anode, a function of transporting the holes, and a function of blocking electrons injected from the cathode is performed. Examples of such materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, polysilane compounds, poly(N-vinylcarbazole) derivatives, aniline copolymers, conductive polymers (e.g., thiophene oligomers and polythiophene), polythiophene derivatives, polyphenylene derivatives, polyphenylene vinylene derivatives, and polyfluorene derivatives. They can be used either individually or as a combination of two or more thereof. A preferred content of the hole transporting material in the light emitting layer is 0 to 99.9% by weight, particularly 0 to 80.0% by weight.

The electron transporting material which can be used in the invention are not limited as long as at least one of a function of injecting electrons from the cathode, a function of transporting electrons, and a function of blocking the holes injected from the anode is performed. Examples of electron transporting materials include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic (e.g., naphthalene or perylene) tetracarboxylic acid anhydrides, phthalocyanine derivatives, metal complexes of 8-quinoliol derivatives, metallo-phthalocyanines, metal complexes having benzoxazole or benzothiazole as a ligand, aniline copolymers, conductive polymers (e.g., thiophene oligomers and polythiophene), polythiophene derivatives, polyphenylene derivatives, polyphenylene vinylene derivatives, and polyfluorene derivatives. The compounds described in JP-A-2001-335776 are also useful. The light-emitting layer preferably contains the electron transporting material in an amount of 0 to 99.9% by weight, particularly 0 to 80.0% by weight.

Examples of binder resins useful for the light emitting layer are polyvinyl chloride, polycarbonate, polystyrene, polymethyl methacrylate, polybutyl methacrylate, polyester, polysulfone, polyphenylene oxide, polybutadiene, hydrocarbon resins, ketone resins, phenoxy resins, polyamide, ethyl cellulose, polyvinyl acetate, ABS resins, polyurethane, melamine resins, unsaturated polyester resins, alkyd resins, epoxy resins, silicone resins, polyvinyl butyral, and polyvinyl acetal. These binder resins can be used either individually or as a mixture thereof. Use of the binder resin is advantageous in that the light emitting layer can be formed easily and over a wide area by a wet film formation technique.

The thickness of the light emitting layer is preferably 10 to 200 nm, still preferably 20 to 80 nm, for controlling an increase of driving voltage and preventing a short circuit of the device.

If necessary, the OLED may have a hole transporting layer containing the above-described hole transporting material in addition to the light emitting layer. The hole transporting layer may contain the above-described binder resin. The thickness of the hole transporting layer is preferably 10 to 200 nm, still preferably 20 to 80 nm, for controlling an increase of driving voltage and preventing a short circuit of the device.

If desired, the OLED may have an electron transport in layer containing the above-described electron transporting material. The electron transporting layer may contain the above-described binder resin. The thickness of the electron transporting layer is preferably 10 to 200 nm, still preferably 20 to 80 nm, for controlling an increase of driving voltage and preventing a short circuit of the device.

If desired, the OLED may further have a hole injecting layer and/or an electron injecting layer. The above-described hole transporting materials and the electron transporting materials can be used to form the hole injecting layer and the electron injecting layer, respectively.

The organic layer is preferably formed by wet film forming techniques, such as dipping, spin coating, dip coating, casting, die coating, roll coating, bar coating, and gravure coating. Wet film formation is advantageous in that an organic layer can easily be formed over a wide area. Solvents that can be used to dissolve the organic layer material to prepare a coating composition is not particularly limited and chosen appropriately according to the kinds of the constituents, such as the hole-transporting material, the ortho-metalated complex, the host material, the binder resin, and so forth. Examples of useful solvents are halogen-containing solvents, such as chloroform, carbon tetrachloride, dichloromethane, 1,2-dichloroethane, and chlorobenzene; ketones such as acetone, methyl ethyl ketone, diethyl ketone, n-propyl methyl ketone, and cyclohexanone; aromatic-solvents, such as benzene, toluene, and xylene; esters, such as ethyl acetate, n-propyl acetate, n-butyl acetate, methyl propionate, ethyl propionate, γ-butyrolactone, and diethyl carbonate; ethers, such as tetrahydrofuran and dioxane; amide solvents, such as dimethylformamide and dimethylacetamide; dimethyl sulfoxide; and water.

Where two or more organic layers are provided, they can be formed by various techniques, including the aforementioned transfer method, the wet film formation techniques as described above, and dry film formation techniques, such as vacuum deposition and sputtering.

Materials of the substrate used in the OLED include inorganic substances, such as yttrium-stabilized zirconia (YSZ) and glass; polymers, such as polyesters, e.g., polyethylene terephthalate, polybutylene terephthalate, and polyethylene naphthalate, polystyrene, polycarbonate, polyether sulfone, polyarylate, allyl diglycol carbonate, polyimide, polycycloolefins, norbornene resins, polychlorotrifluoroethylene, Teflon®, and tetrafluoroethylene-ethylene copolymers; foil of metal, e.g., aluminum, coppers, stainless steel, gold or silver; and liquid crystal polymers.

Flexible substrates are of choice for resistance to breakage, ease of folding, and light weight. Recommended materials for flexible substrates include polyimide, polyester, polycarbonate, polyether sulfone, metal foil (e.g., aluminum, copper, stainless steel, gold or silver), liquid crystal polymers, and fluoropolymers (e.g., polychlorotrifluoroethylene, Teflon, tetrafluoroethylene-ethylene copolymers). They are excellent in heat resistance, dimensional stability, solvent resistance, electrical insulating properties, and processability and exhibit low air permeability and low hygroscopicity.

Metal foils having an insulating layer on one or both sides thereof are of choice as a flexible substrate that prevents a short circuit of the device. Useful metal foils are of aluminum, copper, stainless steel, gold, silver, etc. Aluminum foil and copper foil are preferred for their processability and low price.

The electrically insulating layer is not particularly restricted in material and can be made of, for example, inorganic oxides, inorganic nitrides, or polymers, such as polyester (e.g., polyethylene terephthalate, polybutylene terephthalate, and polyethylene naphthalate), polystyrene, polycarbonate, polyether sulfone, polyarylate, allyl diglycol carbonate, polyimide, polycycloolefins, norbornene resins, polychlorotrifluoroethylene, and polyimide.

The shape, structure, and size of the substrate are not particularly limited and selected, appropriately according to the intended use or purpose of the device. In general, the substrate has a plate shape and may have either a single layer structure or a multilayer structure. It maybe made of a single member or two or more members. The substrate may be either transparent or opaque. Where light is to be extracted from the substrate side, the substrate is preferably colorless transparent or colored transparent. A colorless transparent substrate is still preferred for suppressing light scattering and decay.

In order to prevent the electrode or the organic layer from separating from the substrate by the heat applied during preparation or use and thereby to improve durability of the device, it is preferred for the substrate to have a coefficient of linear thermal expansion of 20 ppm/° C. or smaller. A coefficient of linear thermal expansion of a substrate is measured as a change in length of a sample being heated at a constant rate by, for most cases, thermomechanical analysis (TMA).

In using a metal foil laminated with an insulating layer as a substrate, it is preferred for the insulating layer also to have a coefficient of linear thermal expansion of 20 ppm/° C. or smaller. Materials providing an insulating layer with a linear thermal expansion coefficient of 20 ppm/° C. or smaller include metal oxides, such as silicon oxide, germanium oxide, zinc oxide, aluminum oxide, titanium oxide, and copper oxide, and metal nitrides, such as silicon nitride, germanium nitride, and aluminum nitride and mixtures thereof. The metal oxide and/or metal nitride insulating layer preferably has a thickness of 10 to 1000 nm for maintaining insulating performance. The metal oxide and/or metal nitride insulating layer can be formed by dry film formation techniques such as vacuum deposition, sputtering and CVD, wet processes such as a sol-gel process, or by applying a dispersion of the metal oxide and/or metal nitride particles in a solvent to a metal foil.

Polyimide and liquid crystal polymers are preferably used to make a substrate having a linear thermal expansion coefficient of 20 ppm/° C. or smaller. Details of the properties of such polymer materials are described, e.g., in Plastic Data Book published by Plastic Editorial Department of Asahi Kasei Amidas Co., Ltd. Where polyimide is used as an insulating layer, it is preferably combined with an aluminum foil. The polyimide sheet preferably has a thickness of 10 to 200 μm for ease of handling.

The insulating layer can be provided on one or both sides of the metal foil. In the latter case, the two insulating layers may be made of a metal oxide and/or a metal nitride or a resin, such as polyimide; or one of the insulating layers may be made of a metal oxide and/or a metal nitrile, with the other being made of a resin.

A moisture proof layer (gas barrier layer) may be provided on one or both sides of the substrate. The moisture proof layer is preferably made of an inorganic substance, such is silicon nitride or silicon oxide. The moisture proof layer of such material can be formed by high frequency sputtering or like techniques. If desired, a hard coat or an undercoat may be provided on the substrate.

In order to prevent moisture and/or oxygen permeation into the OLED thereby to secure durability of the device, it is desirable for the substrate to have a moisture permeability (water vapor transmission rate) of 0.1 g/m² day or less, preferably 0.05 g/m² day or less, still preferably 0.01 g/m²-day or less, and an oxygen permeability (gas transmission rate) of 0.1 ml/m² day atm or less, preferably 0.05 ml/mr day atom or less, still preferably 0.01 ml/m² day atm or less. The moisture permeability is measured in accordance with JIS K7129 B method (Mocon method), and the oxygen permeability is measured in accordance with JIS K7126 B method (Mocon method).

The transparent electrode usually serves as an anode supplying positive holes to a light emitting layer, etc. The shape, structure, size, and the like are selected appropriately according to the use of the device. The transparent electrode may be designed to serve as a cathode, in which case the back electrode is designed to function as an anode.

Materials making up the transparent electrode include metals, alloys, metal oxides, electrically conductive organic compounds; and mixtures thereof. Those having a work function of 4.0 eV or higher are preferred for use as an anode. Examples of useful anode materials are semiconductive metal oxides, such as tin oxide doped with antimony or fluorine (ATO or FTO), tin oxide, zinc oxide, indium oxide, indium tin oxide (ITO), and indium zinc oxide (IZO); metals, such as gold, silver, chromium, and nickel; mixtures or laminates of these metals and conductive metal oxides; electrically conductive inorganic substances, such as copper iodide and copper sulfide; electrically conductive organic substances, such as polyaniline, polythiophene, and polypyrrole; and laminates of these materials and ITO.

The transparent electrode is formed on the substrate by an appropriate technique selected according to the material from, for example, wet film formation processes including printing and wet coating, physical processes including vacuum deposition, sputtering, and ion plating, and chemical processes including CVD and plasma-enhanced CVD. For instance, an ITO electrode is formed by direct current or radio frequency sputtering, vacuum deposition or ion plating. Where an organic conductive compound is chosen as a transparent electrode material, the electrode can be formed by wet film formation.

The position where the transparent electrode is formed is not particularly limited and determined according to the intended use, and purpose of the device. The transparent electrode is generally formed on the substrate. In this case, the transparent electrode may be provided on either part of or the whole of a side of the substrate. In the former case, patterning of the transparent electrode is carried out by chemical etching by photolithography, physical etching by laser machining, or vacuum deposition or sputtering through a mask by a lift-off process and a printing process.

The thickness of the transparent electrode is decided appropriately according to the material and usually ranges from 10 nm to 50 μm, preferably 50 nm to 20 μm. To control heat generation and improve stability and durability of the device, the transparent electrode preferably has a surface resistivity of 10³ Ω/square or less, still preferably 10² Ω/square or less.

The transparent electrode may be either colorless or colored but preferably has a transmittance of 60% or higher, particularly 70% or higher, to guarantee high light extraction efficiency. The transmittance is measured in a known manner with a spectrophotometer.

Details of a transparent electrode are described in Sawada Yutaka (ed.), Tomei Denkyokumaku no Shin-tenkai, CMC (1999), which can be applied to the present invention. Where a plastic substrate with low heat resistance is used, an ITO or IZO electrode formed at or below. 150° C. is recommended.

The back electrode usually serves as a cathode supplying electrons to a light emitting layer, etc. The shape, structure, size, etc. of the back electrode are not particularly limited and selected from among known electrodes according to the use of the device. The back electrode may be designed to serve as an anode, in which case the transparent electrode is designed to function as a cathode.

Materials making up the back electrode include metals, alloys, metal oxides, electrically conductive organic compounds, and mixtures thereof. Those having a work function of 4.5 eV or less are preferred for making a cathode. Examples of useful materials for making a cathode are alkali metals (e.g., Li, Na, and K), alkaline earth metals (e.g., Mg and Ca), gold, silver, lead, aluminum, sodium-potassium alloys, lithium-aluminum alloys, magnesium-silver alloys, rare earth metals (e.g., indium and ytterbium), and electrically conductive organic compounds such as polythiophene, polypyrrole, and poly-p-phenylene vinylene or ion-doped compounds thereof. While effective even when used individually, these materials are preferably used as a combination of two or more thereof, for assuring both stability and electron injection capabilities.

Preferred of the recited materials are alkali metals and alkaline earth metals for their electron injection capabilities. Aluminum-based materials are particularly preferred for their storage stability. The term “aluminum-based materials” includes aluminum and an alloy or mixture of aluminum with 0.01 to 10% by weight of an alkali metal or an alkaline earth metal, e.g., a lithium aluminum alloy or a magnesium-aluminum alloy. For the details of back electrode materials reference can be made in JP-A-2-15595 and JP-A-5-121172.

The back electrode can be formed by any known method chosen according to the material from, for example, wet film formation by printing or coating; physical film formation including vacuum deposition, sputtering, and ion plating; and chemical film formation including CVD and plasma-enhanced CVD. For example, a metal or like back electrode can be formed by sputtering a metallic material or materials. In using two or more materials, they may be sputtered either simultaneously or sequentially. Patterning of the back electrode is carried out by chemical etching by photolithography, physical etching by laser machining, or vacuum deposition or sputtering through a mask by a lift-off process or a printing process.

While the position of the back electrode in the device is not particularly limited and is selected appropriately according to the use of the device, the back electrode is preferably formed on an organic layer. It is formed on either the entire area or a part of the organic layer. It is preferred to provide a dielectric layer of, for example, an alkali metal fluoride or an alkaline earth metal-fluoride to a thickness of 0.1 to 5 nm between the organic layer and the back electrode so as to improve electron injection capabilities. Such a dielectric layer can be formed by vacuum deposition, sputtering, ion plating, etc.

The thickness of the back electrode is decided appropriately according to the material and usually ranges from 10 nm to 5 μm, preferably 50 nm to 1 μm. The back electrode may be either transparent or opaque. A transparent back electrode can be formed by forming a film as thin as 1 to 10 nm of the above recited material and laminating the thin film with a transparent conductive material such as ITO or IZO.

The OLED preferably has a protective layer and a sealing layer for preventing deterioration of the luminescence performance.

Useful protective layers are described in JP-A-7-85974, JP-A-7-192866, JP-A-8-22891, JP-A-10-275682, and JP-A-10-106746.

The protective layer is provided as a top layer of the OLED. Where the device has a transparent electrode, an organic layer, and a back electrode on a substrate in that order, the term “top layer” as used herein means an outermost layer provided on the back electrode. Where the device has a back electrode, an organic layer, and a transparent electrode on a substrate in that order, the term “top layer” means an outermost layer provided on the transparent electrode.

The protective layer is not particularly in material, shape, size, and thickness. Any material that prevents substances which would deteriorate the device, such as moisture and oxygen, from entering the device can be used. Such materials typically include silicon monoxide silicon dioxide, germanium monoxide, and germanium dioxide. Methods for forming the protective layer include, but are not limited to, vacuum evaporation, sputtering, reactive sputtering, molecular beam epitaxy, cluster ion beam-assisted deposition, ion plating, plasma polymerization, plasma-enhanced CVD, laser-assisted CVD, thermal CVD, and wet coating techniques.

A sealing layer for preventing moisture or oxygen from entering the device is preferably provided. Materials of the sealing layer include tetrafluoroethylene copolymers, fluorine-containing copolymers having a cyclic structure in the main chain thereof, polyethylene, polymethyl methacrylate, polyimide, polyurea, polytetrafluoroethylene, polychlorotrifluoroethylene, polydichlorodifluoroethylene, chlorotrifluoroethylene copolymers, dichlorodifluoroethylene copolymers; water absorbing substances having a water absorption of at least 1%; moisture-proof substances having a water absorption of 0.1% or less; metals, e.g., In, Sn, Pb, Au, Cu, Ag, Al, Ti, and Ni; metal oxides, e.g., MgO, SiO, SiO₂, Al₂O₃, GeO, NiO, CaO, BaO, Fe₂O₃, Y₂O₃, and TiO₂; metal fluorides, e.g., MgF₂, LiF, AlF₃, and CaF₂; liquid fluorocarbons, e.g., perfluoroalkanes, perfluoroamines, and perfluoroethers; and liquid fluorocarbons having dispersed therein a moisture- or oxygen-adsorbent.

For the purpose of shielding the OLED from outside moisture or oxygen, the organic layer can be sealed with a sealing member, such as a seal plate or a seal container. The sealing member is not limited in shape, size, thickness, etc. as long as the organic layer can be sealed against outside air. The sealing member may be disposed only on the back electrode side, or the whole laminate containing the organic layer may be covered with the sealing member. Materials of the sealing member include glass, stainless steel, metals (e.g., aluminum), resins (e.g., polychlorotrifluoroethylene, polyester, and polycarbonate), and ceramics.

If necessary, a sealant (adhesive) can be used to dispose the sealing member on the laminate. Where the whole laminate is covered with a sealing member, separate sealing member pieces may be bonded together by fusion without using a sealant. Useful sealants include ultraviolet curing resins, heat curing resins, and two-pack type curing resins.

The space between a sealing container and the OLED may be filled with a moisture absorbent or an inert liquid. Useful moisture absorbents include, but are not limited to, barium oxide, sodium oxide, potassium oxide, calcium oxide, sodium sulfate, calcium sulfate, magnesium sulfate, phosphorus pentoxide, calcium chloride, magnesium chloride, copper chloride; cesium fluoride, niobium fluoride, calcium bromide, vanadium bromide, molecular sieve, zeolite, and magnesium-oxide. Useful inert liquids include paraffins, liquid paraffins, fluorine-containing solvents (e.g., perfluoroalkanes, perfluoroamines, and perfluoroethers), chlorine-containing solvents, and silicone oils.

The OLED emits light on applying a direct current voltage (which may contain an alternating component, if needed) usually of 2 to 40 V between the anode and the cathode. For driving the OLED, the methods taught in JP-A-2-148687, JP-A-6-301355, JP-A-5-29080, JP-A-7-134558, JP-A-8-234685, JP-A-8-241047, U.S. Pat. Nos. 5,828,429 and 6,023,308, and Japanese Patent 2784615 can be utilized.

### EXAMPLES

The present invention will now be illustrated in greater detail with reference to Examples, but it should be understood that the present invention is not deemed to be limited thereto. Unless otherwise noted, all the parts and percents are by weight.

### Example 1

Pyrene (1% (weight ratio) of pyrene was doped in a binder (PVK)), a luminescent compound, was applied to a glass substrate by spin coating to a thickness of about 1 μm. Grooves of lattice pattern were made in the coating layer by photolithography. The grooves each had a width of about 10 μm and a pitch of 100 μm. A coated sample having no grooves was also prepared. Each of the coated samples was irradiated with ultraviolet rays (254 nm) to cause the pyrene to emit light. The lumen (lm) of the emitted light was measured with a spectroradiometer SR-3, supplied by Topcon. The results proved that the sample having the grooves showed about 1.3 times the lumen of the sample with no grooves.

### Example 2

1) Preparation of Monochromatic Film

A 6 μm thick polyethylene terephthalate carrier film was coated with each of RBG inks (luminescent materials) having the following compositions with a die coater. The ink was applied to a width of 1 m at a rate of 20 m/min and dried to prepare a set of three monochromatic films. The dry thickness of the thus formed light emitting layer was about 50 nm for every color.

Ink Composition for Red Light Emitting Layer:

| | |
|---|---|
| BTIrQ (bis (2-phenylbenzothiazole)iridium | 1 part |
| 8-hydroxyquinolate) | |
| PVK (N-vinylcarbazole) | 40 parts |
| PBD | 12 parts |
| (2-(4′-t-butylphenyl)-5-(4″- | |
| (phenyl)phenyl)-1,3,4-ox adiazole) | |
| 1,2-Dichloroethane | 3200 parts |

Ink composition for Green Light Emitting Layer:

| | |
|---|---|
| Ir(ppy)₃ | 1 part |
| PVK | 40 parts |
| PBD | 12 parts |
| 1,2-Dichloroethane | 3200 parts |

Ink Composition for Blue Light Emitting Layer:

| | |
|---|---|
| Pt(ppy)₂Br₂ | 1 part |
| PVK | 40 parts |
| 1,2-Dichloroethane | 3200 parts |

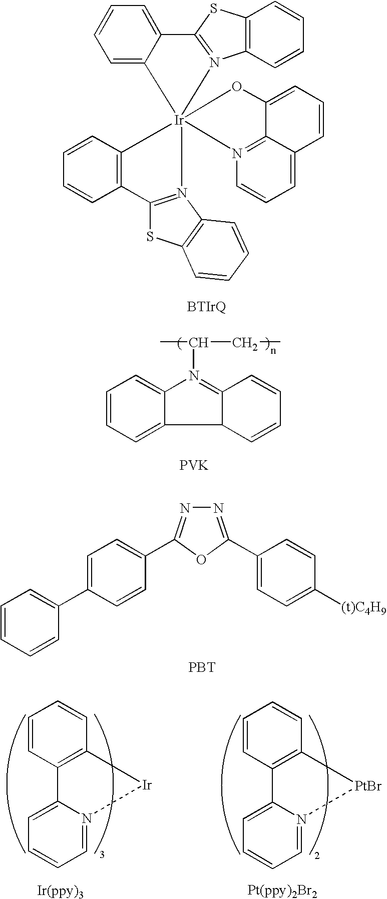

2) Preparation of Laminate A

A 50 μm thick polyimide film (UPILEX-50S, available from Ube Industries, Ltd.) was cleaned with isopropyl alcohol and subjected to oxygen plasma treatment. Aluminum was deposited on the plasma treated side of the film under a reduced pressure of about 0.1 mPa to form an electrode having a thickness of 0.2 μm. Lithium fluoride was then vacuum deposited on the Al electrode (in the same pattern as the Al electrode) to form a dielectric layer having a thickness of 3 nm. An aluminum lead was connected to the aluminum electrode to form an electrode structure.

An electron transporting compound shown below was vacuum deposited on the LiF layer under a reduced pressure of about 0.1 mPa to form an electron transporting layer having a thickness of 9 nm.

Electron Transporting Compound:

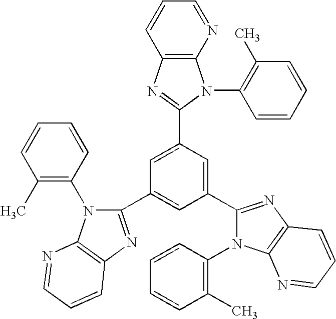

The three light emitting layers of the monochromatic films (transfer materials) were pattern wise transferred successively to the electron transporting layer according to the procedure shown in FIG. 3 to form a matrix pattern made up of RBG pixels 22a, 22b, and 22c as shown in FIG. 4. The pixel size was 100 μm×100 μm for each color, and the distance between pixels was varied between 0 μm and 50 μm. There was thus obtained a laminate A with a color pattern.

The patternwise transfer was carried out with pressing means in combination with heating means. An engraved roll having a prescribed pattern of projections on its peripheral surface was used as a pressing member 30 in combination with a back-up roll to perform patterning in a continuous manner. It is also possible to carry out pattern wise transfer in a batch system by using, for example, a flat engraved plate in place of the engraved roll.

3) Preparation of Transparent Laminate B

A 0.7 mm thick glass plate was set in a vacuum chamber of a DC magnetron sputtering system, and an ITO target (indium:tin=95:5 by mole) containing 10% SnO₂ was sputtered under conditions of a substrate temperature of 250° C. and an oxygen pressure of 1×10⁻³ Pa to form a transparent ITO electrode having a thickness of 0.2 μm. The ITO thin film had a surface resistivity of 10 Ω/square. An aluminum lead was connected to the ITO transparent electrode to form a transparent electrode structure.

The transparent electrode structure was cleaned with isopropyl alcohol and subjected to oxygen plasma treatment. An aqueous dispersion of polyethylenedioxythiophene doped with polystyrene (PEDOT-PSS) (Baytron P®, available from Bayer AG) was applied to the plasma treated ITO electrode by spin coating at 2000 rpm for 60 seconds and dried at 100° C. in vacuo for 1 hour to form a 100 nm thick hole transporting layer. The transparent electrode structure/hole transporting layer laminate is designated laminate B.

PEDOT-PSS:

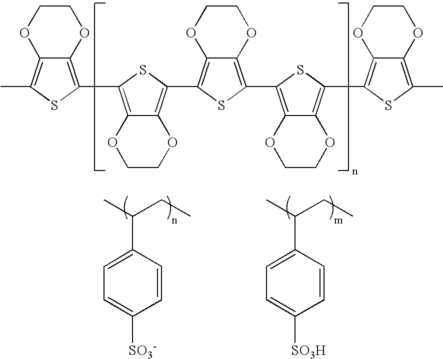

4) Preparation of Multi-Color OLED

The laminates A and B were superposed with their organic layer sides facing each other and bonded together by passing through a pair of hot rolls at 160° C., 0.3 MPa, and 0.05 m/min to prepare a multi-color OLED.

5) Evaluation

The luminescence efficiency (lm/W) of the resulting OLEDs was measured with a spectroradiometer SR-3, supplied by Topcon. As a result, devices having a gap between pixels achieved a maximum of about 1.2 times the luminescence efficiency of a device having no such gaps. The improving effect on luminescence efficiency was observed when the gap between pixels was about 10 μm or greater.

The self emissive light emitting diode of the present invention has a light emitting layer composed of a light emitting region and a low refractive region. At least part of the interface between the light emitting region and the low refractive region is unparallel to the plane of the electrodes. By this design, the light that might be waveguided and trapped inside the device can be taken outside the device to increase the light extraction efficiency, which leads to improved luminescent efficiency.

This application is based on Japanese Patent application JP2003-85832, filed Mar. 26, 2003, the entire content of which is hereby incorporated by reference, the same as if set forth at length.

What is claimed is:

1. A light emitting diode comprising:
a pair of electrodes; and
a light emitting layer interposed between the pair of electrodes,
wherein
the light emitting layer has a light emitting region containing a luminescent material and having a higher refractive index than air and a low refractive region having a lower refractive index than the light emitting region, and
at least part of an interface between the light emitting region and the low refractive region is unparallel to a plane 8 of the electrodes.

2. The light emitting diode according to claim 1, wherein at least part of an interface between the light emitting region and the low refractive region is perpendicular to a plane of the electrodes.

3. The light emitting diode according to claim 1, wherein the low refractive region has air as a medium.

4. The light emitting diode according to claim 1, which is an organic light emitting diode wherein the light emitting region is formed of an organic compound.

5. The light emitting diode according to claim 1, wherein a ratio of a refractive index of the low refractive region to a refractive index of the light emitting region is 0.85 or smaller to 1.

6. The light emitting diode according to claim 1, wherein a ratio of a refractive index of the low refractive region to a refractive index of the light emitting region is 0.7 or smaller to 1.

7. The light emitting diode according to claim 1, wherein the light emitting layer has a thickness of 10 to 200 nm.

8. The light emitting diode according to claim 1, wherein the light emitting layer has a thickness of 20 to 80 nm.

9. The light emitting diode according to claim 1, further comprising a hole transporting layer containing a hole transporting material.

10. The light emitting diode according to claim 1, further comprising an electron transporting layer containing an electron transporting material.
